(19) United States
(12) Patent Application Publication
(10) Pub. No.: US 2025/0378225 A1
(43) Pub. Date: Dec. 11, 2025

(54) DYNAMIC RENDERING IN DIGITAL TWIN

(71) Applicant: International Business Machines Corporation, Armonk, NY (US)

(72) Inventors: Dong Hui Liu, Beijing (CN); Peng Hui Jiang, Beijing (CN); Jing Lu, Beijing (CN); Jun Su, Beijing (CN); Xiang Zu, Beijing (CN); Jia Yu, Beijing (CN)

(21) Appl. No.: 18/738,504

(22) Filed: Jun. 10, 2024

(51) Int. Cl. G06F 30/20

(52) U.S. Cl. CPC G06F 30/20

(57) ABSTRACT

Disclosed is a computer-implemented method, system, and computer program product for dynamic rendering in digital twins. In embodiments, one or more factors that will change over a first time interval among a plurality of factors affecting a plurality of data objects representing the digital twin can be predicted by processing units. The data objects can be grouped into a plurality of groups by processing units based on correlations between the one or more factors and the plurality of data objects. Respective priorities of the plurality of groups can be determined by processing units. A priority of each of the plurality of groups can be determined based on correlations between the plurality of factors and the data objects in each group. The data objects can be rendered by groups by processing units based on the priorities of the plurality of groups in the first time interval.

### BACKGROUND

The present disclosure relates to dynamic rendering in a digital twin, and more specifically, to a computer-implemented method, a system and a computer program product for dynamic rendering of data objects in a digital twin.

Digital twins relate to a new technology, which simulates, analyzes and optimizes a whole life cycle of a physical entity (i.e., a real world entity) by establishing a model completely consistent with performance of the physical entity in the digital world. Digital twins have gained widespread adoption across diverse domains, serving as instrumental tools to articulate and comprehend intricate interconnections within complex systems. The operational essence of digital twins hinges on the dynamic integration of real-time data, ensuring a current and precise portrayal of the entities involved. Digital twins serve as instrumental aides in unraveling the complexities inherent in interdependent systems, elucidating the mutual influences and relationships among various elements. The role of digital twins is foundational in decision-making processes, offering a comprehensive visualization and analytical framework to facilitate informed choices based on temporal behavior of entities.

### SUMMARY

According to one embodiment of the present disclosure, there is provided a computer-implemented method for dynamic rendering in a digital twin. In the computer-implemented method, one or more factors that will change over a first time interval among a plurality of factors affecting a plurality of data objects representing the digital twin can be predicted by one or more processing units. The data objects can be grouped into a plurality of groups by one or more processing units based on correlations between the one or more factors and the plurality of data objects. Respective priorities of the plurality of groups can be determined by one or more processing units. A priority of each of the plurality of groups can be determined based on correlations between the plurality of factors and the data objects in each group. The data objects can be rendered by groups by one or more processing units based on the priorities of the plurality of groups in the first time interval.

According to another embodiment of the present disclosure, there is provided a system for dynamic rendering in a digital twin. The system can comprise one or more processors, a memory coupled to at least one of the processors and a set of computer program instructions stored in the memory. When executed by at least one of the processors, the set of computer program instructions can perform the following actions. One or more factors that will change over a first time interval among a plurality of factors affecting a plurality of data objects representing the digital twin can be predicted. The data objects can be grouped into a plurality of groups based on correlations between the one or more factors and the plurality of data objects. Respective priorities of the plurality of groups can be determined. A priority of each of the plurality of groups can be determined based on correlations between the plurality of factors and the data objects in each group. The data objects can be rendered by groups based on the priorities of the plurality of groups in the first time interval.

According to yet another embodiment of the present disclosure, there is provided computer program product for dynamic rendering in a digital twin. The computer program product can comprise a computer readable storage medium readable by a processing circuit and storing instructions for execution by the processing circuit for performing the following actions. One or more factors that will change over a first time interval among a plurality of factors affecting a plurality of data objects representing the digital twin can be predicted. The data objects can be grouped into a plurality of groups based on correlations between the one or more factors and the plurality of data objects. Respective priorities of the plurality of groups can be determined. A priority of each of the plurality of groups can be determined based on correlations between the plurality of factors and the data objects in each group. The data objects can be rendered by groups based on the priorities of the plurality of groups in the first time interval.

### BRIEF DESCRIPTION OF THE DRAWINGS

Through the more detailed description of some embodiments of the present disclosure in the accompanying drawings, the above and other objects, features and advantages of the present disclosure will become more apparent, wherein the same reference generally refers to the same components in the embodiments of the present disclosure.

FIG. 1 shows an exemplary computing environment which is applicable to implement the embodiments of the present disclosure;

FIG. 2 shows a flowchart of a method for dynamic rendering in a digital twin according to an embodiment of the present disclosure;

FIG. 3 shows an exemplary correlation matrix in the form of a heatmap according to an embodiment of the present disclosure;

FIG. 4 shows one way of implementing a step in FIG. 2 according to an embodiment of the present disclosure;

FIG. 5 shows another way of implementing the step in FIG. 2 according to an embodiment of the present disclosure; and

FIG. 6 shows a system for dynamic rendering in a digital twin according to an embodiment of the present disclosure.

### DETAILED DESCRIPTION

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer-readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as dynamic rendering code 200. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

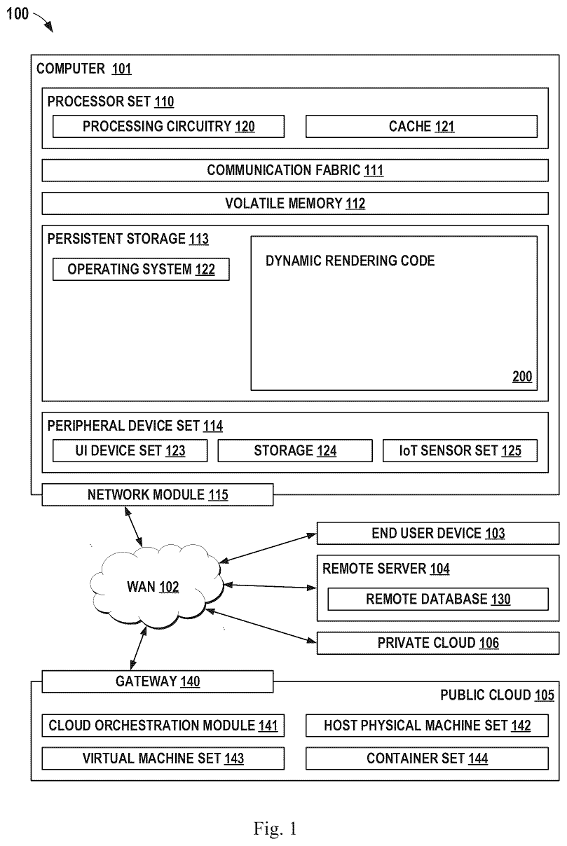

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer-readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer-readable program instructions are stored in various types of computer-readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer-readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

CLOUD COMPUTING SERVICES AND/OR MICROSERVICES (not separately shown in FIG. 1): private and public clouds 106 are programmed and configured to deliver cloud computing services and/or microservices (unless otherwise indicated, the word “microservices” shall be interpreted as inclusive of larger “services” regardless of size). Cloud services are infrastructure, platforms, or software that are typically hosted by third-party providers and made available to users through the internet. Cloud services facilitate the flow of user data from front-end clients (for example, user-side servers, tablets, desktops, laptops), through the internet, to the provider's systems, and back. In some embodiments, cloud services may be configured and orchestrated according to as “as a service” technology paradigm where something is being presented to an internal or external customer in the form of a cloud computing service. As-a-Service offerings typically provide endpoints with which various customers interface. These endpoints are typically based on a set of APIs. One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with these things. Another category is Software as a Service (SaaS) where software is centrally hosted and allocated on a subscription basis. SaaS is also known as on-demand software, web-based software, or web-hosted software. Four technological sub-fields involved in cloud services are: deployment, integration, on demand, and virtual private networks.

It is understood that the computing environment 100 in FIG. 1 is only provided for illustration purpose without suggesting any limitation to any embodiment of this disclosure, for example, at least part of the program code involved in performing the inventive methods could be loaded in cache 121, volatile memory 112 or stored in other storage (e.g., storage 124) of the computer 101, or at least part of the program code involved in performing the inventive methods could be stored in other local or/and remote computing environment and be loaded when need. For another example, the peripheral device 114 could also be implemented by an independent peripheral device connected to the computer 101 through interface. For a further example, the WAN may be replaced and/or supplemented by any other connection made to an external computer (for example, through the Internet using an Internet Service Provider).

As discussed above, the operational essence of digital twin hinges on the dynamic integration of real-time data. However, it is still challenging to render real-time changes within digital twins dynamically, which necessitates sophisticated algorithms and methodologies to ensure accuracy and responsiveness.

Embodiments of the present disclosure aim to solve the technical problem described above, and propose a method, a system and computer program product for dynamic rendering in a digital twin, which can achieve prioritized rendering in a digital twin system based on significance of changes and make real-time rendering more effective.

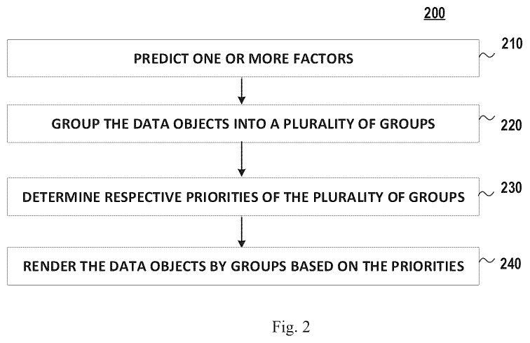

With reference now to FIG. 2, it is shown a flowchart of a method 200 for dynamic rendering in a digital twin according to an embodiment of the present disclosure. As known by the skilled in the art, a digital twin can be designed to model a physical entity, the physical entity can be, for example, an air conditioner, a server, a power source, a storage device, or even a workshop of a factory including all the above-mentioned devices as well as operators and various wirings. In order to model a real-time or historical behavior of the physical entity, the digital twin may include a plurality of data objects to reflect characteristics or performances of the physical entity. Taking the physical entity being a server as an example, the data objects to represent the digital twin of the physical entity may include CPU usage of the server, temperature of the server, I/O throughput of the server, the workload of the server, and so on. Method 200 can be implemented for example in the computing environment of FIG. 1.

At step 210, one or more factors that will change over a first time interval among a plurality of factors affecting a plurality of data objects representing the digital twin can be predicted. There may be dynamic changes to the data objects over time caused by various factors. These factors may include, for example, ambient temperature, power supply, total number of air conditioners, and so on. Again, taking the physical entity being a server as an example, if the ambient temperature as a factor changes, the temperature of the server as a data object may change accordingly, while other data objects such as CPU usage of the server may not experience significant changes. In contrast, if the workload of the server as a factor changes, the CPU usage of the server as a data object may change accordingly, while the temperature of the server as a data object may not experience significant changes. For another example, assuming that the physical entity is a workshop of a factory including air conditioners, servers, storage device, operators and various wirings, if the ambient temperature as a factor changes, the temperature of the server as well as the workload of the air conditioners as data objects may change accordingly. These factors may change over time, which in turn causes changes to the data objects. There may be a plurality of factors related to the data objects to represent the digital twin, and for a certain upcoming time interval, some or all of the plurality of factors may change. In order to model the real-time behavior of the physical entity and anticipate potential issues with the physical entity, the present disclosure proposes to predict one or more factors that will change over a first time interval among a plurality of factors related to the data objects. The first time interval may be predetermined according to experience or decided by a user according to actual application scenario.

In some embodiments, step 210 can be performed using at least one time series model based on historical data about changes of the plurality of factors. For example, the plurality of factors can be monitored in a time sequence to capture their dynamic changes over time, and the captured changes over time can be stored as historical data to be utilized for predicting future states of the plurality of factors. For predicting, at least one time series model can be used. That is, a user may choose a first time series model for predicting a first factor and choose a second time series model, which is different from the first time series model, for predicting a second factor, or a user may choose one common time series model for predicting both the first factor and the second factor. Using a common time series model for predicting different factors may reduce complexity of algorithm and thus saving storage space, while using a respective time series model for predicting a certain factor may increase accuracy. The user may choose the total number and/or type of the at least one time series model according to experience or actual needs. The at least one time series model can be selected from well-known predictive models such as AR (auto regressive) model, MA (moving average) model, ARIMA (autoregressive integrated moving average) model, SARIMA (seasonal autoregressive integrated moving average) model and so on.

At step 220, the data objects can be grouped into a plurality of groups based on correlations between the one or more factors and the plurality of data objects. There may be for example thousands of data objects, and in order to facilitate processing, the data objects can be firstly grouped into groups. As described above, the factors and the data objects may have correlations. A change to a factor may induce a change to one or more data objects. The one or more factors predicted at step 210 are the ones that will change over the first time interval, and the present disclosure proposes to group the data objects into groups based on correlations between the one or more factors and the plurality of data objects. Whenever there is one or more factors that will change over the first time interval, the grouping of the data objects into groups based on the correlations will be performed. In this way, the grouping reflects changes of the factors, and the resulting groups can dynamically change over time, which makes dynamic rendering of data objects with changes in a later rendering stage more effective and efficient.

In some embodiments, the correlations between the plurality of factors and the plurality of data objects can be derived from historical data about data object changes with respect to factor changes. The correlations may be represented in many forms. For example, the correlations can be indicated by numerical values. In this case, for each factor of the plurality of factors, historical data about a change of the factor over a certain time interval and corresponding changes of the plurality of data objects can be collected to derive respective correlations between the factor and the plurality of data objects. As a specific example, if a first factor A changes by increasing 50% over a certain time interval, and a corresponding data object B changes by increasing 30% over the certain time interval, then the correlation between the first factor A and the data object B can be determined as 30%/50%=0.6. In contrast, if the first factor A changes by increasing 50% over a certain time interval, and the data object B changes by decreasing 30% over the certain time interval, then the correlation between the first factor A and the data object B can be determined as (−30%)/50%=−0.6. The correlations can also be indicated by levels. For example, the correlation between a first factor A and a data object B may be indicated as level 1, and the correlation between the first factor A and a data object C may be indicated as level 2, with level 2 indicating a stronger correlation than level 1.

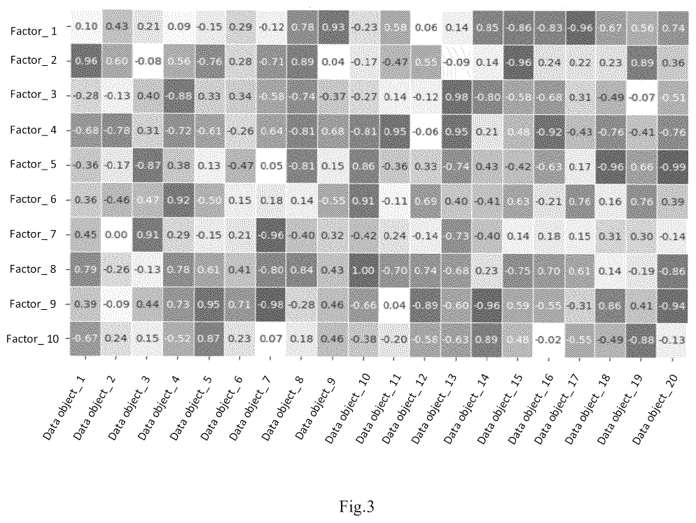

The correlations between the plurality of factors and the plurality of data objects may be predetermined and prestored as a correlation matrix for ease of future use. Optionally, the correlations may also be normalized to a certain value range. With reference now to FIG. 3, it is shown an exemplary correlation matrix in the form of a heatmap according to an embodiment of the present disclosure, with 10 factors listed in the vertical direction, and 20 data objects listed in the horizontal direction. For example, it can be determined from FIG. 3 that the correlation between Factor_1 and data object_1 is −0.1, and the correlation between Factor_2 and data object_6 is 0.28, etc.

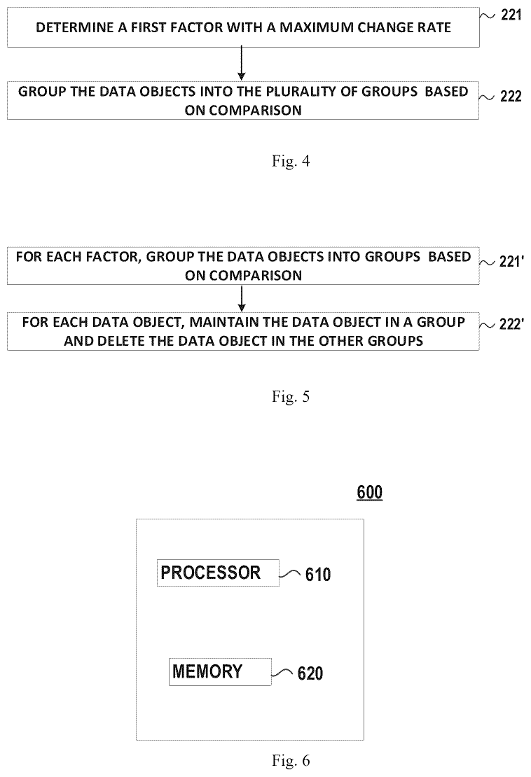

There may be various ways to implement step 220. With reference now to FIG. 4, it is shown one way of implementing step 220 according to an embodiment of the present disclosure. As shown in FIG. 4, step 220 may include sub-steps 221-222. At sub-step 221, a first factor with a maximum change ratio over the first time interval among the one or more factors can be determined. Among the plurality of factors, there may be one or more factors which are predicted to change, and sub-step 221 aims to find out the one factor which changes most significantly over the first time interval.

At sub-step 222, the data objects can be grouped into the plurality of groups based on comparison of the correlations between the first factor and the plurality of data objects with threshold values. For example, the total number n of the plurality of groups into which the data objects are to be grouped, as well as corresponding n−1 threshold values can be set by the user or according to default settings. For example, the total number n can be set as 4, and 3 threshold values for distinguishing between the groups can be set correspondingly, and accordingly, the data objects can be grouped into 4 groups based on comparison of the correlations between the first factor and the plurality of data objects with the 3 threshold values. As a more specific example and with a reference to the correlations shown in FIG. 3 which are normalized to a value range of (−1, 1), assuming that the first factor with a maximum change ratio determined at sub-step 221 is Factor_3, the total number of the plurality of groups is 4 and the corresponding 3 threshold values are (−0.3), 0.2 and 0.7 respectively. After comparing the threshold values with the correlations between Factor_3 and the 20 data objects, the resulting 4 groups are (Data object_4, Data object_7, Data object_8, Data object_9, Data object_14, Data object_15, Data object_16, Data object_18, Data object_20), (Data object_1, Data object_2, Data object_10, Data object_11, Data object_12, Data object_19), (Data object_3, Data object_5, Data object_6, Data object_17), and (Data object_13).

With reference now to FIG. 5, it is shown another way of implementing step 220 according to an embodiment of the present disclosure. As shown in FIG. 5, step 220 may include sub-steps 221′-222′. In contrast to the solution in FIG. 4 which determines the first factor with a maximum change ratio at first, in FIG. 5, no discriminations between factors are made firstly. Instead, for each factor j of the one or more factors, the data objects can be grouped into r groups based on comparison of the correlations between the factor j and the plurality of data objects with r−1 threshold values. Sub-step 221′ is similar to sub-step 222 described above, the difference may lie in the number of groups, details are omitted herein for conciseness. It should be noted that, the number r of the groups and the corresponding number r−1 of the threshold values can be set the same or different for different factors of the one or more factors by the user or by default settings. Still referring to the correlations shown in FIG. 3, and simply for ease of description but not intended for limitation, assuming that Factor _1 and Factor_2 are predicted to change over the first time interval, the number r of groups for both Factor_1 and Factor_2 is set as 2, and the corresponding 1 threshold value for both Factor_1 and Factor_2 is set as 0.4. Accordingly, a total number of 2*r=4 groups are obtained, which are group 1 (Data object_2, Data object_8, Data object_9, Data object_11, Data object_14, Data object_18, Data object_19, Data object_20) and group 2 (Data object_1, Data object_3, Data object_4, Data object_5, Data object_6, Data object_7, Data object_10, Data object_12, Data object_13, Data object_15, Data object_16, Data object_17) defined by Factor _1, and group 3 (Data object_2, Data object_4, Data object_8, Data object_12, Data object_19) and group 4 (Data object_1, Data object_3, Data object_5, Data object_6, Data object_7, Data object_9, Data object_10, Data object_11, Data object_13, Data object_14, Data object_15, Data object_16, Data object_17, Data object_18, Data object_20) defined by Factor_2. It can be seen that each data object falls into 2 (which number corresponds to the number of factors predicted to change over the first time interval) groups, for example, Data object_9 falls into group 1 and group 4. The following sub-steps 222′ aims at selecting one particular group from the groups resulted from sub-step 221′ for one particular data object to stay in.

For each data object p of the plurality of data objects, at sub-step 224′, the data object p can be maintained in a group defined by a factor with a maximum correlation with the data object p and can be deleted from the other groups. Continuing with the above example, Data object_9 falls into group 1 defined by Factor_1 and group 4 defined by Factor_2, and correlations of Data object_9 with Factor_1 and Factor_2 are 0.93 and 0.04 respectively, therefore, Data object_9 finally maintains in group 1 defined by Factor_1 and is deleted from group 4 defined by Factor_2. After the sub-step 222′ is performed, each data object maintains in one single group, and the grouping of data objects are completed. It can be understood that the way for implementing step 220 as shown in FIG. 5 may result in more groups than the way for implementing step 220 as shown in FIG. 4.

The two ways for implementing step 220 as shown in FIG. 4 and FIG. 5 both consider the correlations between factors and data objects as a whole, and therefore can reflect the influence of factor changes on the data objects. In addition, the way for implementing step 220 as shown in FIG. 4 takes into account the change ratios of the factors and therefore may better reflect the influence of the factor changes on the data objects and need less computation, while the way for implementing step 220 as shown in FIG. 5 may result in more groups, leading to a finer classification of the data objects and therefore may achieve better rendering at a later stage. It should be understood that the way for implementing step 220 as shown in FIG. 4 or FIG. 5 is just an example, the present disclosure is not limited thereto.

In some embodiments, step 220 can be performed further based on dependencies among the plurality of data objects, and the data objects with dependencies can be grouped into a same group. Data objects not only have correlations with the factors, but also may have dependencies on each other. If a change of a data object A may result in a change of a data object B, then it can be said that the two data objects have dependencies. Although a particular factor A may not have a strong correlation with a data object B, it may have a strong correlation with a data object C, and data objects B and C may have dependencies. For example, considering an instance where two data objects of a server are CPU usage and I/O throughput respectively and the factor is workload of the server, the CPU usage of the server may have a strong correlation with the workload of the server, and may be grouped into a group A, while the I/O throughput of the server may have a weak correlation with the workload of the server, and may be grouped into a group B. However, the CPU usage of the server may have influence on the I/O throughput of the server, i.e., they have dependencies on each other. According to some embodiments of the present disclosure, the CPU usage of the server and the I/O throughput of the server should be arranged in the same group, for example, by adjusting the I/O throughput of the server from group B to group A. The present disclosure proposes to consider the dependencies among the data objects in the grouping of the data objects, so that associated data objects may be arranged in the same group, which may make later rendering of the groups of data objects to be more efficiently and systematically.

With reference now back to FIG. 2, at step 230, respective priorities of the plurality of groups can be determined. Specifically, a priority of each of the plurality of groups can be determined based on correlations between the plurality of factors and the data objects in each group. The present disclosure proposes to render the data objects by groups in sequence, and in order to determine the rendering sequence, priorities of the plurality of groups can be determined. For the determining, correlations between the plurality of factors and the data objects in each group can be taken into account.

In some embodiments, step 230 can include determining a priority of group i in the plurality of groups based on the following equation 1:

$${POG}_{i} = {\sum }_{j = 1}^{m} \vert {VOF}_{j} * {COFG}_{ji} \vert , \qquad ( Equation 1 )$$

wherein i represents a group index ranging from 1 to n, n represents a total number of the plurality of groups, m represents a total number of the plurality of factors, j represents a factor index ranging from 1 to m, POGᵢ represents the priority of group i, VOFⱼ represents a change ratio of factor j, and COFGⱼᵢ represents a correlation between factor j and group i.

In some embodiments, the COFGⱼᵢ appearing in the above equation 1 can be determined based on the following equation 2:

$${COFG}_{ji} = \frac{{\sum }_{p = 1}^{q} \vert {COF}_{pj} \vert}{q} , \qquad ( Equation 2 )$$

wherein q represents a total number of data objects in group i, p represents a data object index ranging from 1 to q, and COFₚⱼ represents a correlation between data object p and factor j.

The above way for determining the respective priorities of the plurality of groups takes into account both the correlations between factors and data objects and the change ratios of the factors, which provides a comprehensive assessment of the influence of factor changes on the groups of data objects, and therefore generating a fair priority for each group. It should also be understood that the particular way for determining the priorities of the plurality of groups described above is just an example, the present disclosure is not limited thereto.

At step 240, the data objects can be rendered by groups in the first time interval based on the priorities of the plurality of groups determined at step 230. In this way, a group of data objects with higher priority may be rendered earlier than a group of data objects with lower priority, and therefore the embodiments of the present disclosure can achieve rendering based on the significance of changes, which facilitates addressing potential issue quickly, and make real-time rendering more effective.

In view of the above, embodiments of the present disclosure can achieve prioritized rendering in a digital twin system based on significance of changes and make real-time rendering more effective.

Referring now to FIG. 6, it is shown a system 600 for dynamic rendering in a digital twin according to an embodiment of the present disclosure. The system 600 can comprise one or more processors 610 and a memory 620 coupled to at least one of the processors 610. A set of computer program instructions are stored in the memory 620. When executed by at least one of the processors 610, the set of computer program instructions perform following series of actions for dynamic rendering in a digital twin. One or more factors that will change over a first time interval among a plurality of factors affecting a plurality of data objects representing the digital twin can be predicted. The data objects can be grouped into a plurality of groups based on correlations between the one or more factors and the plurality of data objects. Respective priorities of the plurality of groups can be determined. A priority of each of the plurality of groups can be determined based on correlations between the plurality of factors and the data objects in each group. The data objects can be rendered by groups based on the priorities of the plurality of groups in the first time interval.

In some embodiments, the determining the respective priorities of the plurality of groups can comprise determining a priority of group i in the plurality of groups according to the above equation 1.

In some embodiments, the COFGⱼᵢ appearing in the above equation 1 can be determined according to the above equation 2.

In some embodiments, the grouping the data objects into the plurality of groups can comprise: determining a first factor with a maximum change ratio among the one or more factors; and grouping the data objects into the plurality of groups based on comparison of the correlations between the first factor and the plurality of data objects with threshold values.

In some embodiments, the grouping the data objects into the plurality of groups can comprise the following steps. For each factor j of the one or more factors, grouping the data objects into r groups based on comparison of the correlations between the factor j and the plurality of data objects with r−1 threshold values. For each data object p of the plurality of data objects, maintaining the data object p in a group defined by a factor with a maximum correlation with the data object p and deleting the data object p from the other groups.

In some embodiments, the grouping the data objects into the plurality of groups can be further based on dependencies among the plurality of data objects, and the data objects with dependencies can be grouped into a same group.

In some embodiments, the correlations between the plurality of factors and the plurality of data objects can be derived from historical data about data object changes with respect to factor changes.

In some embodiments, the correlations between the plurality of factors and the plurality of data objects can be prestored as a correlation matrix.

In some embodiments, the predicting the one or more factors that will change over the first time interval can be performed using at least one time series model based on historical data about changes of the plurality of factors.

In some embodiments, the at least one time series model can comprise an autoregressive integrated moving average model (ARIMA).

The descriptions above related to the process of method 200 can be applied to system 600, details are omitted herein for conciseness.

It should be noted that the processing of the computer-implemented method for dynamic rendering in a digital twin or the processing achieved by the system for dynamic rendering in a digital twin according to embodiments of this disclosure could be implemented in the computing environment of FIG. 1.

According to another embodiment of the present disclosure, a computer program product for dynamic rendering in a digital twin is disclosed. The computer program product can comprise a computer readable storage medium readable by a processing circuit and storing instructions for execution by the processing circuit for performing one or more of the above described actions.

The present disclosure may be a system, a method, and/or a computer program product at any possible technical detail level of integration. The computer program product may include a computer readable storage medium (or media) having computer readable program instructions thereon for causing a processor to carry out aspects of the present disclosure.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A computer-implemented method for dynamic rendering in a digital twin, comprising:
predicting, by one or more processing units, one or more factors that will change over a first time interval among a plurality of factors affecting a plurality of data objects representing the digital twin;
grouping, by one or more processing units, the data objects into a plurality of groups based on correlations between the one or more factors and the plurality of data objects;
determining, by one or more processing units, respective priorities of the plurality of groups, wherein a priority of each of the plurality of groups is determined based on correlations between the plurality of factors and the data objects in each group; and
rendering, by one or more processing units, the data objects by groups based on the priorities of the plurality of groups in the first time interval.

2. The computer-implemented method of claim 1, wherein the determining the respective priorities of the plurality of groups comprises determining a priority of group i in the plurality of groups as follows:
$${POG}_{i} = {\sum }_{j = 1}^{m} \vert {VOF}_{j} * {COFG}_{ji} \vert ,$$
wherein i represents a group index ranging from 1 to n, n represents a total number of the plurality of groups, m represents a total number of the plurality of factors, j represents a factor index ranging from 1 to m, POGᵢ represents the priority of group i, VOFⱼ represents a change ratio of factor j, and COFGⱼᵢ represents a correlation between factor j and group i.

3. The computer-implemented method of claim 2, wherein the COFGⱼᵢ is determined as follows:
$${COFG}_{ji} = \frac{{\sum }_{p = 1}^{q} \vert {COF}_{pj} \vert}{q} ,$$
wherein q represents a total number of data objects in group i, p represents a data object index ranging from 1 to q, and COFₚⱼ represents a correlation between data object p and factor j.

4. The computer-implemented method of claim 1, wherein the grouping the data objects into the plurality of groups comprises:
determining, by one or more processing units, a first factor with a maximum change ratio over the first time interval among the one or more factors; and
grouping, by one or more processing units, the data objects into the plurality of groups based on comparison of the correlations between the first factor and the plurality of data objects with threshold values.

5. The computer-implemented method of claim 1, wherein the grouping the data objects into the plurality of groups comprises:
for each factor j of the one or more factors:
grouping, by one or more processing units, the data objects into r groups based on comparison of the correlations between the factor j and the plurality of data objects with r−1 threshold values; and
for each data object p of the plurality of data objects:
maintaining, by one or more processing units, the data object p in a group defined by a factor with a maximum correlation with the data object p and deleting the data object p from the other groups.

6. The computer-implemented method of claim 1, wherein the grouping the data objects into the plurality of groups is further based on dependencies among the plurality of data objects, and the data objects with dependencies are grouped into a same group.

7. The computer-implemented method of claim 1, wherein the correlations between the plurality of factors and the plurality of data objects are derived from historical data about data object changes with respect to factor changes.

8. The computer-implemented method of claim 1, wherein the correlations between the plurality of factors and the plurality of data objects are prestored as a correlation matrix.

9. The computer-implemented method of claim 1, wherein the predicting the one or more factors that will change over the first time interval are performed using at least one time series model based on historical data about changes of the plurality of factors.

10. The computer-implemented method of claim 9, wherein the at least one time series model comprises an autoregressive integrated moving average model (ARIMA).

11. A system for dynamic rendering in a digital twin, comprising:
one or more processors;
a memory coupled to at least one of the processors;
a set of computer program instructions stored in the memory, which, when executed by at least one of the processors, perform actions of:
predicting one or more factors that will change over a first time interval among a plurality of factors affecting a plurality of data objects representing the digital twin;
grouping the data objects into a plurality of groups based on correlations between the one or more factors and the plurality of data objects;
determining respective priorities of the plurality of groups, wherein a priority of each of the plurality of groups is determined based on correlations between the plurality of factors and the data objects in each group; and
rendering the data objects by groups based on the priorities of the plurality of groups in the first time interval.

12. The system of claim 11, wherein the determining the respective priorities of the plurality of groups comprises determining a priority of group i in the plurality of groups as follows:
$${POG}_{i} = {\sum }_{j = 1}^{m} \vert {VOF}_{j} * {COFG}_{ji} \vert ,$$
wherein i represents a group index ranging from 1 to n, n represents a total number of the plurality of groups, m represents a total number of the plurality of factors, j represents a factor index ranging from 1 to m, POGᵢ represents the priority of group i, VOFⱼ represents a change ratio of factor j, and COFGⱼᵢ represents a correlation between factor j and group i.

13. The system of claim 12, wherein the COFGⱼᵢ is determined as follows:
$${COFG}_{ji} = \frac{{\sum }_{p = 1}^{q} \vert {COF}_{pj} \vert}{q} ,$$
wherein q represents a total number of data objects in group i, p represents a data object index ranging from 1 to q, and COFₚⱼ represents a correlation between data object p and factor j.

14. The system of claim 11, wherein the grouping the data objects into the plurality of groups comprises:
determining a first factor with a maximum change ratio among the one or more factors; and
grouping the data objects into the plurality of groups based on comparison of the correlations between the first factor and the plurality of data objects with threshold values.

15. The system of claim 11, wherein the grouping the data objects into the plurality of groups comprises:
for each factor j of the one or more factors:
grouping the data objects into r groups based on comparison of the correlations between the factor j and the plurality of data objects with r−1 threshold values; and
for each data object p of the plurality of data objects:
maintaining the data object p in a group defined by a factor with a maximum correlation with the data object p and deleting the data object p from the other groups.

16. The system of claim 11, wherein the grouping the data objects into the plurality of groups is further based on dependencies among the plurality of data objects, and the data objects with dependencies are grouped into a same group.

17. The system of claim 11, wherein the correlations between the plurality of factors and the plurality of data objects are derived from historical data about data object changes with respect to factor changes.

18. The system of claim 11, wherein the correlations between the plurality of factors and the plurality of data objects are prestored as a correlation matrix.

19. The system of claim 11, wherein the predicting the one or more factors that will change over the first time interval are performed using at least one time series model based on historical data about changes of the plurality of factors.

20. A computer program product for dynamic rendering in a digital twin, the computer program product comprising:
a computer readable storage medium readable by a processing circuit and storing instructions for execution by the processing circuit for performing actions of:
predicting one or more factors that will change over a first time interval among a plurality of factors affecting a plurality of data objects representing the digital twin;
grouping the data objects into a plurality of groups based on correlations between the one or more factors and the plurality of data objects;
determining respective priorities of the plurality of groups, wherein a priority of each of the plurality of groups is determined based on correlations between the plurality of factors and the data objects in each group; and
rendering the data objects by groups based on the priorities of the plurality of groups in the first time interval.
